(19) United States
(12) Patent Application Publication
(10) Pub. No.: US 2022/0352461 A1
(43) Pub. Date: Nov. 3, 2022

(54) SEMICONDUCTOR DEVICE INCLUDING ACTIVE LAYER WITH VARIABLE RESISTANCE

(71) Applicant: SK hynix Inc., Icheon-si (KR)

(72) Inventors: Won Tae KOO, Icheon-si (KR); Jae Hyun HAN, Icheon-si (KR); Jae Gil LEE, Icheon-si (KR)

(73) Assignee: SK hynix Inc.

(21) Appl. No.: 17/496,971

(22) Filed: Oct. 8, 2021

(30) Foreign Application Priority Data
Apr. 30, 2021 (KR) 10-2021-0056927

(51) Int. Cl. H01L 45/00

(52) U.S. Cl. CPC H01L 45/085; H01L 45/1206; H01L 45/147

(57) ABSTRACT

A semiconductor device according to an embodiment includes a substrate, a source electrode layer and a drain electrode layer that are disposed to be spaced apart from each other on the substrate, an active layer disposed on the substrate to contact the source electrode layer and the drain electrode layer, and a gate electrode layer disposed on the active layer. The active layer includes metal oxide capable of exsolving and reincorporating metal particles. The electrical resistance in the active layer is configured to be reversibly changed by exsolution and reincorporation of the metal particles.

### CROSS-REFERENCE TO RELATED APPLICATIONS

The present application claims priority under 35 U.S.C. § 119(a) to Korean Application No. 10-2021-0056927, filed on Apr. 30, 2021 in the Korean Intellectual Property Office, which is incorporated herein by reference in its entirety.

### BACKGROUND

### 1. Technical Field

The present disclosure generally relates to a semiconductor device, and more particularly, to a semiconductor device including an active layer with variable resistance.

### 2. Related Art

In general, in the field of electronic devices, a resistance change material may refer to a material whose internal electrical resistance changes when an external stimulus such as heat, pressure, voltage, or current is applied thereto. Some resistance change materials with changed electrical resistance may maintain that resistance in a non-volatile manner even after the external stimulus is removed. Accordingly, resistive memory devices that utilize changeable electrical resistance as signal information have emerged. The resistive memory devices may include, for example, a resistance change random access memory (RAM), a phase change RAM, a magnetic change RAM, or the like.

Recently, with respect to resistive memory devices, various studies are being conducted to improve their performance, such as increasing the number of resistance states that can be implemented in the resistance change material, increasing the magnitude ratio between the plurality of resistance states that are implemented, increasing linearity and symmetry between the plurality of resistance states that may be implemented, or increasing a drive speed of the resistive memory device. These studies may include research on a new resistance change material and a new resistance change mechanism using the new material.

### SUMMARY

A semiconductor device according to an embodiment of the present disclosure may include a substrate, a source electrode layer and a drain electrode layer that are disposed to be spaced apart from each other on the substrate, an active layer disposed on the substrate to contact the source electrode layer and the drain electrode layer, and a gate electrode layer disposed on the active layer. The active layer may include metal oxide capable of exsolving and reincorporating metal particles. The electrical resistance in the active layer is configured to be reversibly changed by exsolution and reincorporation of the metal particles.

A semiconductor device according to another embodiment of the present disclosure may include a substrate, an active layer disposed on the substrate and including metal oxide capable of exsolving and reincorporating metal particles, and a gate electrode layer disposed on the active layer. The electrical resistance in the active layer is configured to be reversibly changed by exsolution and reincorporation of the metal particles.

A semiconductor device according to yet another embodiment of the present disclosure may include a substrate, a resistance change memory layer disposed on the substrate and including metal oxide capable of exsolving and reincorporating metal particles, a source electrode layer and a drain electrode layer that are disposed on the substrate to be spaced apart from each other and to contact portions of the resistance change memory layer, a gate electrode layer disposed to contact the resistance change memory layer and electrically insulated from the source electrode layer and the drain electrode layer, and a conductive channel disposed inside the resistance change memory layer between the source electrode layer and the drain electrode layer. The conductive channel may include the metal particles exsolved from the metal oxide.

### BRIEF DESCRIPTION OF THE DRAWINGS

FIG. 1 is a schematic cross-sectional view illustrating a semiconductor device according to an embodiment of the present disclosure.

FIG. 2 is a schematic view illustrating a lattice structure of metal oxide of a semiconductor device according to an embodiment of the present disclosure.

FIGS. 3A and 3B are schematic views illustrating a first write operation of a semiconductor device and an active layer of the semiconductor device after the first write operation according to an embodiment of the present disclosure.

FIGS. 4A and 4B are schematic views illustrating a second write operation of a semiconductor device and an active layer of the semiconductor device after the second write operation according to an embodiment of the present disclosure.

FIG. 5 is a schematic view illustrating a read operation of a semiconductor device according to an embodiment of the present disclosure.

FIG. 6 is a schematic cross-sectional view illustrating an electronic device according to another embodiment of the present disclosure.

FIG. 7 is a schematic cross-sectional view illustrating an electronic device according to another embodiment of the present disclosure.

FIG. 8 is a schematic cross-sectional view illustrating a semiconductor device according to yet another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. Generally, when describing the drawings, descriptions are provided from the viewpoint of an observer, and when an element is referred to as being positioned over another element, this includes both an element positioned directly on the other element or an additional element interposed between the elements. The same reference numerals in the plurality of drawings refer to elements that are substantially the same as each other.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

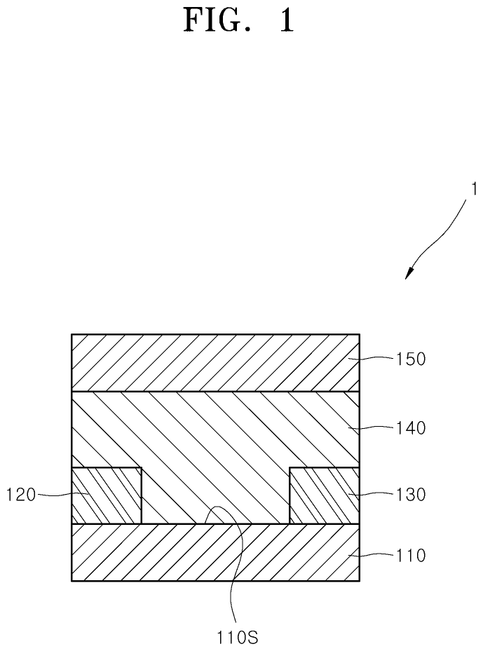

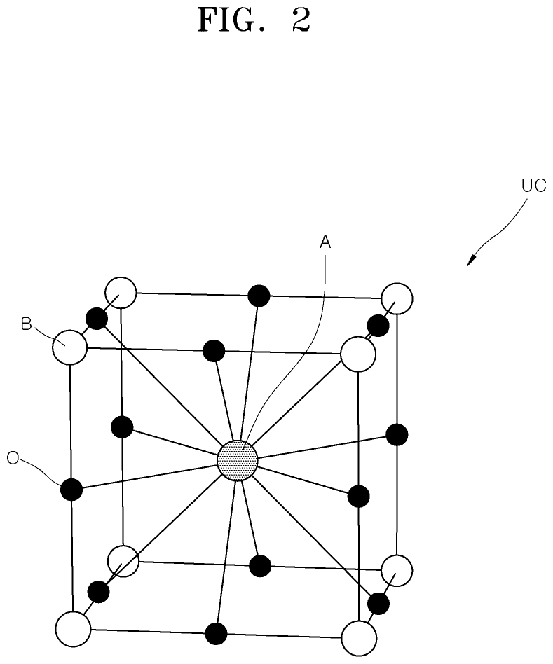

FIG. 1 is a schematic cross-sectional view illustrating a semiconductor device according to an embodiment of the present disclosure. FIG. 2 is a schematic view illustrating a lattice structure of metal oxide of a semiconductor device according to an embodiment of the present disclosure.

Referring to FIG. 1, a semiconductor device 1 may include a substrate 110, a source electrode layer 120 and a drain electrode layer 130 that are disposed to be spaced apart from each other on the substrate 110, an active layer 140 disposed to contact the source electrode layer 120 and the drain electrode layer 130 on the substrate 110, and a gate electrode layer 150 disposed on the active layer 140. The active layer 140 may include a metal oxide capable of exsolving and reincorporating metal particles.

In an embodiment, the substrate 110 may include a semiconductor material. As an example, the semiconductor material may include silicon (Si), gallium arsenide (GaAs), indium phosphide (InP), germanium (Ge), silicon germanium (SiGe), or a combination of two or more thereof. In an embodiment, the substrate 110 may be formed by doping a layer of the semiconductor material with an n-type or p-type dopant to have electrical conductivity. In another embodiment, the substrate 110 may remain in a non-doped state. A non-doped state may mean a state in which intentional doping is not performed on the substrate 110.

Referring to FIG. 1, the source electrode layer 120 and the drain electrode layer 130 may be disposed to be spaced apart from each other on a surface 110S of the substrate 110. Each of the source electrode layer 120 and the drain electrode layer 130 may include a conductive material. The conductive material may include, for example, highly doped semiconductor material, metal, conductive metal nitride, conductive metal oxide, conductive metal silicide, conductive metal carbide, or a combination of two or more thereof. The conductive material may include, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. In an example, if the substrate 110 is doped with a dopant, then the electrical conductivity of each of the source electrode layer 120 and the drain electrode layer 130 may be higher than that of the substrate 110.

Referring to FIG. 1, the active layer 140 may be disposed on the surface 110S of the substrate 110 to cover the source electrode layer 120 and the drain electrode layer 130. The active layer 140 may include metal oxide capable of exsolving and reincorporating metal particles.

Exsolving may refer to a phenomenon in which metal atoms of the metal oxide are precipitated on a surface of the metal oxide by a reduction reaction. In the reduction reaction, electrons may be supplied from the substrate 110 to the active layer 140 under a first gate voltage applied between the gate electrode layer 150 and the substrate 110. The electrons combine with metal ions constituting the metal oxide, as will be described later. Reincorporation of metal particles may refer to a phenomenon in which the metal atoms that are precipitated on the surface of the metal oxide lose electrons through an oxidation reaction. The metal particles are converted into metal oxide. In the oxidation reaction, precipitated metal atoms are deprived of electrons that move to the substrate 110 and bond with oxygen under a second gate voltage applied between the gate electrode layer 150 and the substrate 110, as will be described later.

When exsolving of metal particles occurs by the application of a first gate voltage having positive polarity, the metal particles precipitated in the active layer 140 may be distributed and may electrically connect each other. As a result, because the precipitated metal particles have electrical conductivity, the electrical resistance of the active layer 140 may be reduced. Even after the first gate voltage is removed, the exsolved metal particles may be distributed in the active layer 140 while maintaining electrical connections. Accordingly, the active layer 140 may maintain a reduced electrical resistance.

By application of a second gate voltage having negative polarity, exsolved metal particles may be reincorporated so that the density of the exsolved metal particles distributed in the active layer 140 may decrease. Accordingly, the electrical resistance of the active layer 140 may increase. Even after the second gate voltage is removed, the active layer 140 may maintain the reduced density of the metal particles. As a result, the active layer 140 may maintain an increased electrical resistance.

As described above, the electrical resistance of the active layer 140 may be reversibly changed depending on whether the metal particles are exsolved or reincorporated. In an embodiment of the present disclosure, the active layer 140 may perform a function of a memory layer which non-volatilely stores electrical resistance as signal information.

In an embodiment, the active layer 140 may include perovskite-based metal oxides. FIG. 2 illustrates a lattice structure for a unit cell (UC) of a perovskite-based metal oxide according to an embodiment of the present disclosure. Referring to FIG. 2, in the lattice structure, a first metal may be disposed at an A site, a second metal may be disposed at a B site, and oxygen may be disposed at an O site. When the perovskite-based metal oxide is reduced, the second metal of the B site may be exsolved and precipitated as metal particles. The perovskite-based metal oxide may include, for example, La_{0.8}Sr_{0.2}Cr_{0.8}Pd_{0.2}O_{3-δ}, La_{0.8}Sr_{0.2}Fe_{0.9}Nb_{0.1}Pd_{0.04}O_{3-δ}, La_{0.8}Sr_{0.2}Cr_{1-y}X_{y}O_{3-δ}(X=Ni, Ru), La_{0.8}Sr_{0.2}Cr_{0.82}Ru_{0.18}O_{3-δ}, La_{0.8}Sr_{0.2}Cr₁₋ₓRuₓO_{3-δ}, LaCr_{0.95}Ir_{0.05}O_{3-δ}, La_{0.5}Sr_{0.5}Ti_{0.75}Ni_{0.25}O_{3-δ}, (La_{0.7}Sr_{0.3})(Cr_{0.85}Ni_{0.1125}Fe_{0.0375})O_{3-δ}, (La_{0.3}Sr_{0.6}Ce_{0.1})Ni_{0.1}Ti_{0.9}O_{3-δ}, La_{0.75}Sr_{0.25}Cr_{0.5}Mn_{0.3}Ni_{0.2}O_{2.8}, La_{0.6}Sr_{0.4}Fe_{0.8}Ni_{0.2}O_{3-δ}, Sr₂Fe_{1.4}Ni_{0.1}Mo_{0.5}O_{6-δ}, or the like.

In another embodiment, the active layer 140 may include an oxide of a first metal doped with a second metal that functions as a dopant. In an embodiment, the oxide of the first metal may be tungsten oxide. The second metal may include iridium (Ir), platinum (Pt), palladium (Pd), ruthenium (Ru), or the like. When the oxide of the first metal doped with the second metal is reduced, the second metal may be precipitated. As the precipitated second metal is oxidized, the precipitated second metal may be converted into the metal oxide. The oxide of the first metal in which the second metal is doped as a dopant may have, for example, a lattice structure similar to that of the perovskite-based metal oxide, but its lattice structure is not limited thereto.

Referring again to FIG. 1, the active layer 140 may be disposed to contact the substrate 110. As will be described later, as electrons are exchanged between the active layer 140 and the substrate 110 under a gate voltage applied between the gate electrode layer 150 and the substrate 110, oxidation-reduction reactions may occur in the active layer 140.

The gate electrode layer 150 may be disposed on the active layer 140. As illustrated in FIG. 1, the gate electrode layer 150 may be disposed to contact the active layer 140. In addition, the gate electrode layer 150 may be disposed to be electrically insulated from the source electrode layer 120 and the drain electrode layer 130.

The gate electrode layer 150 may include a conductive material. The conductive material may include, for example, doped semiconductor, metal, conductive metal oxide, conductive metal nitride, conductive metal silicide, conductive metal carbide, or a combination of two or more thereof. The conductive material may include, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

As described above, a semiconductor device according to an embodiment of the present disclosure may include an active layer including metal oxide capable of exsolving and reincorporating metal particles. The electrical resistance inside the active layer may be reversibly changed by the exsolution and reincorporation of the metal particles. In addition, the changed electrical resistance may be non-volatilely stored in the active layer as signal information. As a result, the semiconductor device may function as a resistance change memory device in which the active layer is used as a resistance change memory layer.

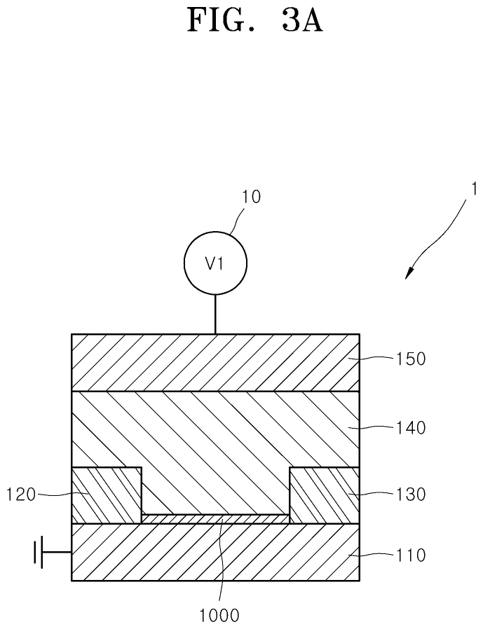

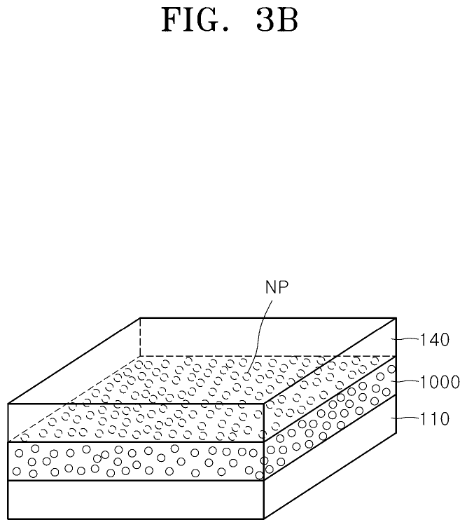

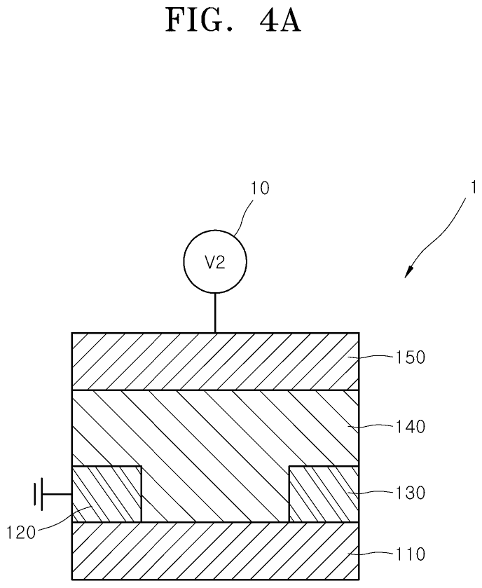

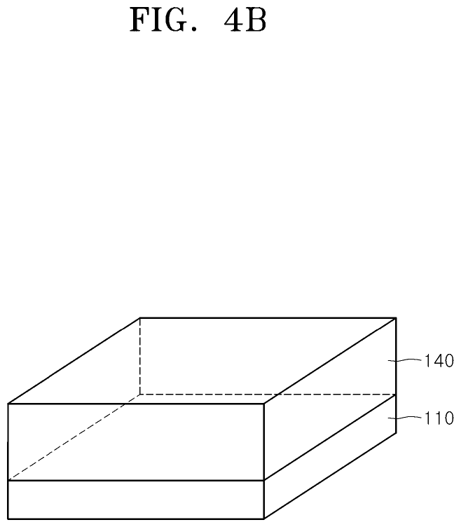

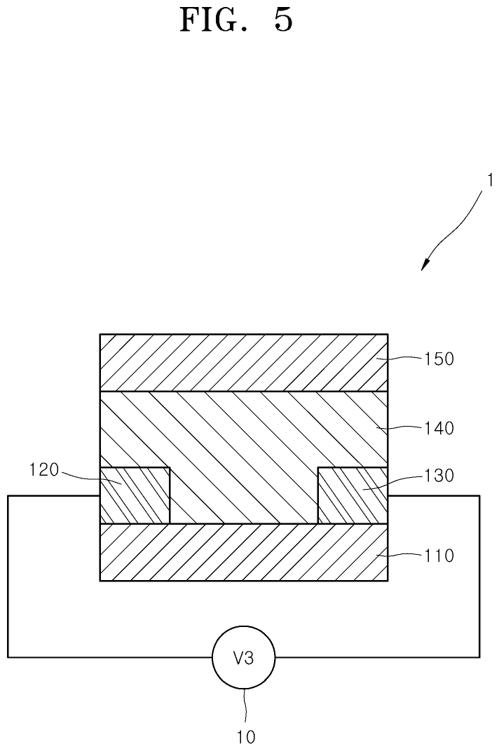

FIG. 3A is a schematic view illustrating a first write operation of a semiconductor device according to an embodiment of the present disclosure. FIG. 3B is a schematic view illustrating an active layer of the semiconductor device after the first write operation of FIG. 3A is performed. FIG. 4A is a schematic view illustrating a second write operation of a semiconductor device according to an embodiment of the present disclosure. FIG. 4B is a schematic view illustrating an active layer of the semiconductor device after the second write operation of FIG. 4A is performed. FIG. 5 is a schematic view illustrating a read operation of a semiconductor device according to an embodiment of the present disclosure. The first and second write operations and the read operation may be used in a method of driving a semiconductor device described above with reference to FIG. 1.

Referring to FIGS. 3A and 3B, the first write operation may be an operation of writing a first resistance state in the active layer 140 of the semiconductor device 1. The resistance value of the first resistance state may be lower than the resistance value of a second resistance state that is the result of the second write operation to be described later.

In an embodiment, the first write operation may be an operation of forming a conductive channel 1000 having electrical conductivity in the active layer 140. Specifically, the conductive channel 1000 may be formed in an inner region of the active layer 140 adjacent an interface between the substrate 110 and the active layer 140. The conductive channel 1000 may electrically connect the source electrode layer 120 and the drain electrode layer 130.

Hereinafter, the first write operation will be described in more detail with reference to FIGS. 3A and 3B. First, a power supply 10 may be provided to the semiconductor device 1. In the first write operation, a first gate voltage V1 having a positive bias may be applied to the gate electrode layer 150 while the substrate 110 is grounded.

Electrons may be supplied from the substrate 110 to the active layer 140 by application of the first gate voltage V1 having a positive polarity. The electrons may be provided from the substrate 110 to the metal oxide inside the active layer 140. In this case, the metal inside the metal oxide may receive the electrons and be exsolved from the metal oxide in the form of metal particles precipitated on a surface of the metal oxide. The exsolution phenomenon of the metal particles may actively proceed in the inner region of the active layer 140 adjacent to the interface between the substrate 110 and the active layer 140. As a result, as illustrated in FIG. 3B, the conductive channel 1000 including exsolved metal particles NP may be formed in the inner region of the active layer 140.

Referring to FIG. 3B, the metal particles NP may be dispersed in the conductive channel 1000. As the metal particles NP constitute an electrically conductive network in the conductive channel 1000, electrons may conduct along the conductive channel 1000. As an example, when an electric field is applied to the conductive channel 1000, the electrons may conduct along the electric field, for example by hopping between the dispersed and distributed metal particles NP.

In an embodiment, the conductive channel 1000 may be configured to electrically connect the source electrode layer 120 to the drain electrode layer 130. Even after the first gate voltage V1 is removed, the conductive channel 1000 may be maintained in the inner region of the active layer 140. Accordingly, as described above, the first write operation of writing the first resistance state to the active layer 140 may be performed.

Referring to FIGS. 4A and 4B, the second write operation may be an operation of writing a second resistance state in the active layer 140 of the semiconductor device 1. The resistance value of the second resistance state may be higher than that of the first resistance state written by the first write operation.

In an embodiment, the second write operation may be an operation of removing at least a portion of an electrically conductive network formed by the metal particles NP distributed in the conductive channel 1000. Accordingly, electrical conduction through the conductive channel 1000 may be hindered in derogation of the electrical connection between the source electrode layer 120 and the drain electrode layer 130, which may be disconnected or cut off.

Although FIGS. 4A and 4B illustrate that all of the exsolved metal particles NP are reincorporated and the conductive channel 1000 disappears as a result of the second write operation, the present disclosure is not limited to this result. In other embodiments, as a result of a second write operation, only a portion of the exsolved metal particles NP constituting the conductive channel 1000 may be removed. Thus, the disconnection between the source electrode layer 120 and the drain electrode layer 130 may also be achieved by removing some of the metal particles NP in the conductive channel 1000.

Hereinafter, the second write operation will be described in more detail with reference to FIGS. 4A and 4B. In the second write operation, using the power supply 10, a second gate voltage V2 having a negative polarity may be applied to the gate electrode layer 150 while the substrate 110 is grounded.

Because the second gate voltage V2 has negative polarity, the metal particles NP precipitated on the surface of the metal oxide in the active layer 140 may lose electrons to the substrate 110 and be oxidized. Accordingly, reincorporation may occur in which the metal particles are converted into metal oxide by an oxidation reaction. As a result, at least some of the metal particles NP distributed in the conductive channel 1000 may be removed, resulting in disconnection between the source electrode layer 120 and the drain electrode layer 130, which may be electrically cut off from each other. That is, the conductive channel 1000 may be electrically disconnected between the source electrode layer 120 and the drain electrode layer 130. Even after the second gate voltage V2 is removed, the electrical disconnection state between the source electrode layer 120 and the drain electrode layer 130 may be maintained. As a result, as described above, the second write operation of writing the second resistance state in the active layer 140 may be performed.

Referring to FIG. 5, a read operation may be an operation of reading the first resistance state or the second resistance state written in the active layer 140 by the first write operation or the second write operation, respectively.

Hereinafter, the read operation will be described in more detail with reference to FIG. 5. First, both terminals of the power supply 10 may be respectively connected to the source electrode layer 120 and the drain electrode layer 130 of the semiconductor device 1. A read voltage V3 may be applied between the source electrode layer 120 and the drain electrode layer 130 to measure the source-drain current flowing through the active layer 140. When the conductive channel 1000 is formed in the active layer 140 by the first write operation, that is, in the first resistance state, the source-drain current may be relatively large. When electrical conduction in the conductive channel 1000 in the active layer 140 is interrupted by the second write operation, that is, in the second resistance state, the source-drain current may be relatively small. By identifying the magnitude of the source-drain current, the first and second resistance states in the active layer 140 may be read.

As described above, according to an embodiment of the present disclosure, the operation of writing signal information in the active layer 140 may be performed to control the electrical resistance of the active layer 140 through exsolving metal particles from the metal oxide or reincorporating the exsolved metal particles. Because the exsolution or reincorporation of the metal particles proceeds through a chemical reaction such as an oxidation-reduction reaction, the semiconductor device according to an embodiment of the present disclosure may operate in a stable manner in a relatively high-temperature and/or high pressure environments. Accordingly, the semiconductor device may have improved durability against external environmental factors. As an example, the semiconductor device according to an embodiment of the present disclosure may be used in a power semiconductor device field that is driven at a temperature of about 100° C. to 400° C.

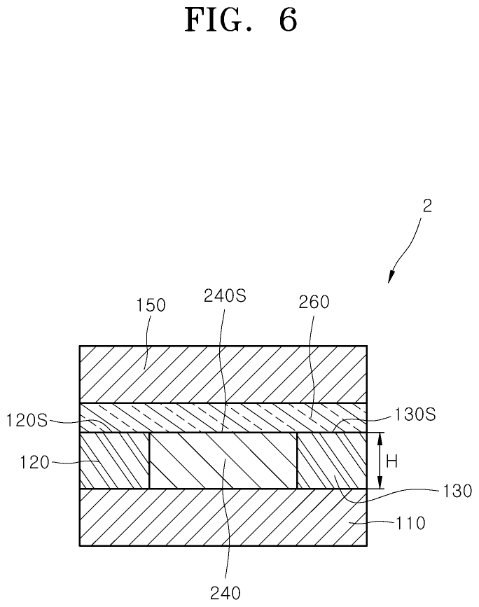

FIG. 6 is a schematic cross-sectional view illustrating an electronic device according to another embodiment of the present disclosure. Referring to FIG. 6, a semiconductor device 2 may be different from a semiconductor device 1 of FIG. 1 with respect to the configuration of an active layer 240. In addition, the semiconductor device 2 may further include a gate insulating layer 260 when compared to the semiconductor device 1 of FIG. 1.

Referring to FIG. 6, the semiconductor device 2 may include a source electrode layer 120 and a drain electrode layer 130 disposed to be spaced apart from each other on a substrate 110. The semiconductor device 2 may include the active layer 240 disposed between the source electrode layer 120 and the drain electrode layer 130 on the substrate 110. The active layer 240 may be made of substantially the same material as the active layer 140 of the semiconductor device 1 of FIG. 1.

As illustrated in FIG. 6, an upper surface 240S of the active layer 240 may be disposed at the same level as an upper surface 120S of the source electrode layer 120 and an upper surface 130S of the drain electrode layer 130. Each of the source electrode layer 120, the active layer 240, and the drain electrode layer 130 may have the same height H on the substrate 110. Accordingly, the active layer 240 of the semiconductor device 2 may have a reduced height H on the substrate 110 when compared to the active layer 140 of the semiconductor device 1 of FIG. 1. As the height H of the active layer 140 is reduced, a gap between the gate electrode layer 150 and the substrate 110 may decrease. Accordingly, it is possible to more effectively control the gate voltage for forming the conductive channel in the active layer 240.

Referring to FIG. 6, the semiconductor device 2 may include a gate insulating layer 260 disposed on the source electrode layer 120, the active layer 240, and the drain electrode layer 130. The gate electrode layer 150 may be disposed on the gate insulating layer 260. The gate insulating layer 260 may electrically insulate the gate electrode layer 150 from the source electrode layer 120 and the drain electrode layer 130. The gate insulating layer 260 may include a dielectric material. The dielectric material may include, for example, oxide, nitride, oxynitride, or a combination of two or more thereof.

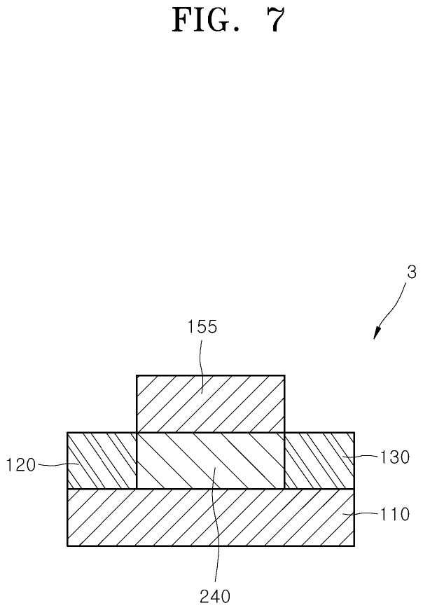

FIG. 7 is a schematic cross-sectional view illustrating an electronic device according to another embodiment of the present disclosure. Referring to FIG. 7, in a semiconductor device 3, the gate insulating layer 260 may be omitted as compared to the semiconductor device 2 of FIG. 6. That is, a gate electrode layer 155 may be disposed to contact the active layer 240. However, the gate electrode layer 155 may be disposed only directly on the active layer 240 so that the gate electrode layer 155 is electrically insulated from the source electrode layer 120 and the drain electrode layer 130.

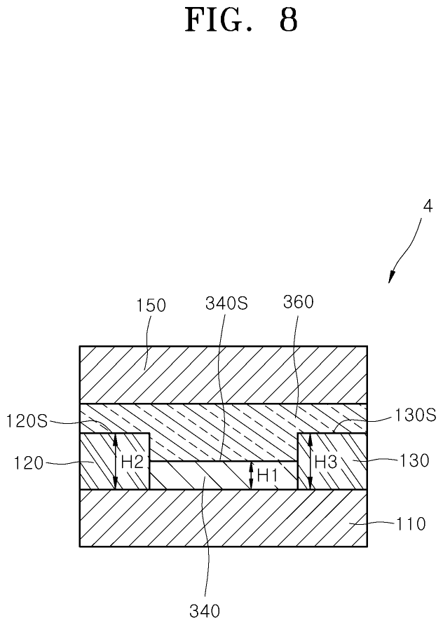

FIG. 8 is a schematic cross-sectional view illustrating a semiconductor device according to yet another embodiment of the present disclosure. Referring to FIG. 8, in a semiconductor device 4, the configuration of the active layer 340 may be different from the configuration of the active layer 240 of the semiconductor device 2 of FIG. 6.

Referring to FIG. 8, the semiconductor device 4 may include a source electrode layer 120 and a drain electrode layer 130 disposed to be spaced apart from each other on a substrate 110. The semiconductor device 4 may include an active layer 340 disposed between the source electrode layer 120 and the drain electrode layer 130 on the substrate 110. The active layer 340 may be made of substantially the same material as the active layer 140 of the semiconductor device 1 of FIG. 1.

As illustrated in FIG. 8, an upper surface 340S of the active layer 340 may be disposed at a level lower than an upper surface 120S of the source electrode layer 120 and an upper surface 130S of the drain electrode layer 130. On the substrate 110, the height H1 of the active layer 340 may be lower than the height H2 of the source electrode layer 120 and the height H3 of the drain electrode layer 130. In an embodiment, the height H2 of the source electrode layer 120 and the height H3 of the drain electrode layer 130 may be the same.

Referring to FIG. 8, a gate insulating layer 360 and a gate electrode layer 150 may be sequentially disposed on the source electrode layer 120, the active layer 340, and the drain electrode layer 130. The gate insulating layer 360 may electrically insulate the gate electrode layer 150 from the source electrode layer 120 and the drain electrode layer 130. The gate insulating layer 360 may be made of substantially the same material as the gate insulating layer 260 of the semiconductor device 2 of FIG. 6.

The active layer 340 of the semiconductor device 4 illustrated in FIG. 8 may have a reduced height H1 on the substrate 110 when compared to the active layer 240 of the semiconductor device 2 of FIG. 6. As the height H1 of the active layer 340 is further reduced compared to the height H of the active layer 240 of the semiconductor device 2, a conductive channel may be more easily formed and distributed in the active layer 340. Accordingly, it is possible to more efficiently control the electrical resistance of the active layer 340.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor device comprising;
a substrate;
a source electrode layer and a drain electrode layer that are disposed to be spaced apart from each other on the substrate;
an active layer disposed on the substrate to contact the source electrode layer and the drain electrode layer and comprising metal oxide capable of exsolving and reincorporating metal particles; and
a gate electrode layer disposed on the active layer,
wherein electrical resistance in the active layer is configured to be reversibly changed by exsolution and reincorporation of the metal particles.

2. The semiconductor device of claim 1, wherein the metal particles are configured to be exsolved under a voltage having positive polarity applied to the gate electrode layer.

3. The semiconductor device of claim 1, further comprising a conductive channel disposed inside the active layer and including exsolved metal particles,
wherein the conductive channel is between the source electrode layer and the drain electrode layer.

4. The semiconductor device of claim 3, wherein the conductive channel has an electrical connection structure comprising the exsolved metal particles.

5. The semiconductor device of claim 3, wherein the conductive channel is disposed in an inner region of the active layer adjacent to an interface between the substrate and the active layer.

6. The semiconductor device of claim 3, wherein the conductive channel is configured to be electrically disconnected by applying a voltage having negative polarity to the gate electrode layer.

7. The semiconductor device of claim 1, wherein the active layer comprises perovskite-based metal oxide.

8. The semiconductor device of claim 1, wherein the active layer comprises oxide of a first metal doped with a dopant of a second metal.

9. The semiconductor device of claim 1, wherein the gate electrode layer is disposed to contact the active layer.

10. The semiconductor device of claim 1, wherein an upper surface of the active layer is disposed on the same level as an upper surface of the source electrode layer and as an upper surface of the drain electrode layer.

11. The semiconductor device of claim 1, wherein an upper surface of the active layer is disposed at a lower level than an upper surface of the source electrode layer and an upper surface of the drain electrode layer.

12. A semiconductor device comprising;
a substrate;
an active layer disposed on the substrate and comprising metal oxide capable of exsolving and reincorporating metal particles; and
a gate electrode layer disposed on the active layer,
wherein electrical resistance in the active layer is configured to be reversibly changed by exsolution and reincorporation of the metal particles.

13. The semiconductor device of claim 12, further comprising a source electrode layer and a drain electrode layer that are disposed to contact the active layer on the substrate.

14. The semiconductor device of claim 13, wherein an upper surface of the source electrode layer and an upper surface of the drain electrode layer are disposed on the same level as an upper surface of the active layer.

15. The semiconductor device of claim 13, wherein an upper surface of the source electrode layer and an upper surface of the drain electrode layer are disposed at a higher level than an upper surface of the active layer.

16. The semiconductor device of claim 13, further comprising a conductive channel disposed in the active layer between the source electrode layer and the drain electrode layer,
wherein the conductive channel has an electrical connection structure comprising the exsolved metal particles.

17. The semiconductor device of claim 16, wherein the conductive channel is disposed in an inner region of the active layer adjacent to an interface between the substrate and the active layer.

18. The semiconductor device of claim 12, wherein the active layer includes perovskite-based metal oxide.

19. The semiconductor device of claim 12, wherein the active layer includes oxide of a first metal doped with a dopant of a second metal.

20. A semiconductor device comprising;
a substrate;
a resistance change memory layer disposed on the substrate and including metal oxide capable of exsolving and reincorporating metal particles;
a source electrode layer and a drain electrode layer that are disposed on the substrate to be spaced apart from each other and to contact portions of the resistance change memory layer;
a gate electrode layer disposed to contact the resistance change memory layer and electrically insulated from the source electrode layer and the drain electrode layer; and
a conductive channel disposed inside the resistance change memory layer between the source electrode layer and the drain electrode layer,
wherein the conductive channel comprises the metal particles exsolved from the metal oxide.
